(19) United States
(12) Patent Application Publication
(10) Pub. No.: US 2019/0043744 A1
(43) Pub. Date: Feb. 7, 2019

(54) ACTIVE MONITORING SYSTEM FOR SUBSTRATE BREAKAGE PREVENTION

(71) Applicant: Applied Materials, Inc., Santa Clara, CA (US)

(72) Inventors: Tom K. CHO, Los Altos, CA (US); Ali SALEHPOUR, Saratoga, CA (US); Stanley WU, San Ramon, CA (US); Ying MA, Castro Valley, CA (US)

(21) Appl. No.: 16/046,105

(22) Filed: Jul. 26, 2018

Related U.S. Application Data
(60) Provisional application No. 62/539,968, filed on Aug. 1, 2017.

(51) Int. Cl. H01L 21/677; H01L 21/67

(52) U.S. Cl. CPC H01L 21/67742; H01L 21/67259

(57) ABSTRACT

A method and apparatus for monitoring substrate lift pin operation is disclosed and includes a support pedestal for a vacuum chamber, the support pedestal comprising a body having a plurality of openings formed between two major sides of the body, and a substrate support device disposed in each of the plurality of openings, each of the support devices comprising a housing disposed in the body, the housing having a bore formed therethrough, and a support pin disposed in the bore, wherein the body includes a monitoring device positioned proximal to the support pins of each of the substrate support devices.

### CROSS-REFERENCE TO RELATED APPLICATION

This application claims benefit of U.S. Provisional Patent Application Ser. No. 62/539,968, filed Aug. 1, 2017, which application is hereby incorporated by reference herein.

### BACKGROUND

### Field

Embodiments disclosed herein generally relate to apparatus and methods for detecting a jammed substrate support pin used in a vacuum chamber.

### Description of the Related Art

Electronic devices, such as thin film transistors (TFT's), photovoltaic (PV) devices or solar cells and other electronic devices have been fabricated on thin, flexible media for many years. The substrates may be made of glass, polymers, or other material suitable for electronic device formation. There is an ongoing effort directed to fabricating the electronic devices on substrates having a surface area much greater than one square meter, such as two square meters, or larger, to produce an end product of a larger size and/or decrease fabrication costs per device (e.g., pixel, TFT, photovoltaic or solar cell, etc.).

The ever-increasing size of these substrates presents numerous handling challenges. The substrate (i.e., thin media) is highly flexible at room temperature and becomes even more flexible at elevated processing temperatures. The flexibility of the thin media, along with the increased surface area, results in greater deflection and/or requires additional areas that must be supported to prevent excess deflection.

To facilitate transfer of the substrate between chambers, substrate support devices including a substrate support pin that may extend through an upper surface of a substrate support based on movement of the substrate support. For example, lowering of the substrate support actuates the substrate support devices such that the support pins contact the substrate such that the substrate may be spaced apart from the substrate support. This spacing allows a transfer mechanism, such as a robot blade or end effector, to move between the substrate and the upper surface of the substrate support and lift the substrate off the substrate support without causing damage to the substrate support or the substrate.

The substrate support pins are typically rigid, vertical posts of fixed height which extend through the substrate support within a housing fixed to the substrate support. During transfer, the substrate is placed on the substrate support pins and the substrate support pins are lowered in relation to the substrate support by movement of (i.e., raising) the substrate support. When the substrate support is raised to a certain height, the support pins are fully retracted relative to the support surface, and the substrate is placed into contact with the substrate support for processing. After film deposition is complete, the substrate support is lowered, which raises the support pins in relation to the substrate support, which lifts the substrate from the substrate support during movement thereof.

A conventional substrate support pin may include a housing, such as a holder or bushing, for example a slide bushing or roller bushing, which is designed to provide lateral support to a support pin and to facilitate movement of the support pin through the housing along an axis perpendicular to the plane of the substrate support. The support pins cannot be held so tightly within the housing such that the pin resists movement therein. On the other hand, the support pins cannot be held too loosely by the housing such that the pins bind due to lateral displacement therein. However, periodically, the support pins may bind or jam, or not operate smoothly due to particle contamination, which typically results in breakage of a substrate.

What is needed are methods and apparatus to monitor substrate support pin operation which may minimize or eliminate substrate breakage.

### SUMMARY

Embodiments described herein provide a method and apparatus for active monitoring of substrate lift pin operation in a chamber, the active monitoring detects abnormal operation of one or more substrate support devices and interlocks (i.e., ceases operation of) the chamber.

In one embodiment, a support pedestal for a vacuum chamber is disclosed and includes a body having a plurality of openings formed between two major sides of the body, and a substrate support device disposed in each of the plurality of openings, each of the support devices comprising a housing disposed in the body, the housing having a bore formed therethrough, and a support pin disposed in the bore, wherein the body includes a monitoring device positioned proximal to the support pins of each of the substrate support devices.

In another embodiment, a vacuum chamber is disclosed and includes a susceptor movably disposed in a processing volume enclosed by a bottom and a sidewall, the susceptor comprising a body having a plurality of openings formed between two major sides of the body, and a substrate support device disposed in each of the plurality of openings, each of the support devices comprising a housing disposed in the body, the housing having a bore formed therethrough, and a support pin disposed in the bore, wherein the sidewall includes a plurality of transparent windows formed therein, and an optical sensor is positioned adjacent to each of the transparent windows in a position to view each of the support devices.

In another embodiment, a method for processing a substrate is disclosed and includes lowering a support pedestal disposed in a processing chamber to a position such that a plurality of support pins suspended in openings in the support pedestal contact a surface in a lower portion of the processing chamber, further lowering the support pedestal while each of the plurality of support pins are guided along an opening in a housing disposed in the support pedestal, and monitoring the operation of each of the support pins during the lowering.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-sectional view of one embodiment of a processing system having a substrate support.

FIG. 1B is a schematic cross-sectional view of the processing chamber of FIG. 1A showing the substrate support in a transfer position.

FIG. 2 is a partial cross-sectional side view of a substrate support having one embodiment of a substrate support device and a lift pin monitoring device.

FIG. 3 is a schematic cross-sectional view of a substrate support pin showing another embodiment of a lift pin monitoring device.

FIG. 4A is a schematic plan view of a substrate support with the chamber body shown in cross section showing another embodiment of a lift pin monitoring device.

FIGS. 4B and 4C are schematic side cross-sectional views of the substrate support and a portion of the chamber body illustrating locations for the optical sensors and/or switch devices.

FIG. 5 is a partial cross-sectional side view of a substrate support having another embodiment of a lift pin monitoring device.

FIG. 6 is a partial cross-sectional side view of a substrate support having another embodiment of a lift pin monitoring device.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein provide a method and apparatus for active monitoring of substrate lift pin operation in a chamber, the active monitoring detects abnormal operation of one or more substrate lift pins and interlocks (i.e., ceases operation of) the chamber. The substrate support pins disclosed herein are particularly suitable for flexible, rectangular media having at least one major side with a surface area greater than one square meter, such as greater than about two square meters, or larger. The substrate support pins may be used in a vacuum chamber adapted to deposit materials on the media to form electronic devices such as thin film transistors, organic light emitting diodes, photovoltaic devices or solar cells. The flexible, rectangular media as described herein may be thin sheet of metal, plastic, organic material, silicon, glass, quartz, or polymeric materials, among other suitable materials. The method and apparatus includes one or more monitoring devices to monitor operation of the substrate support pins.

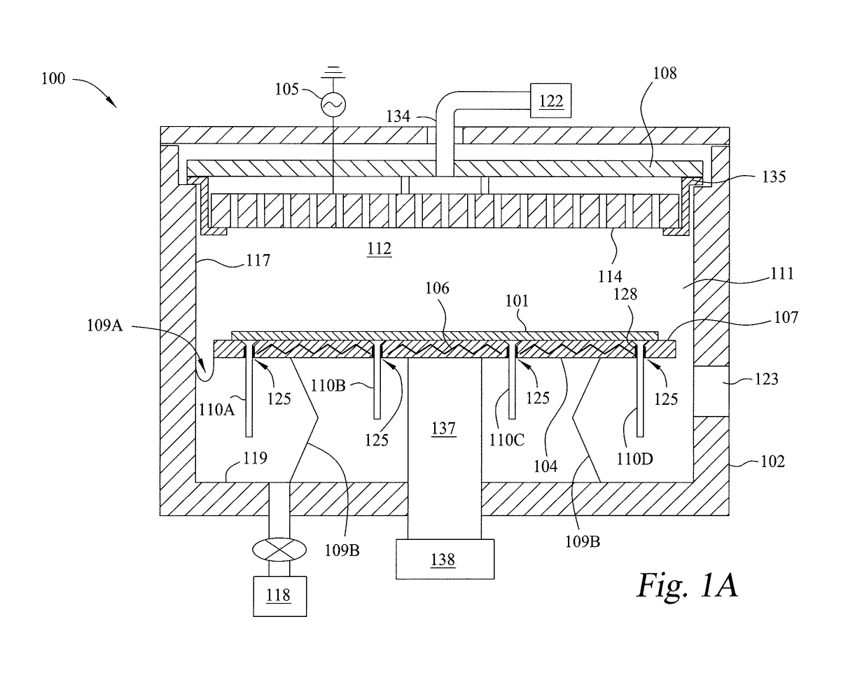

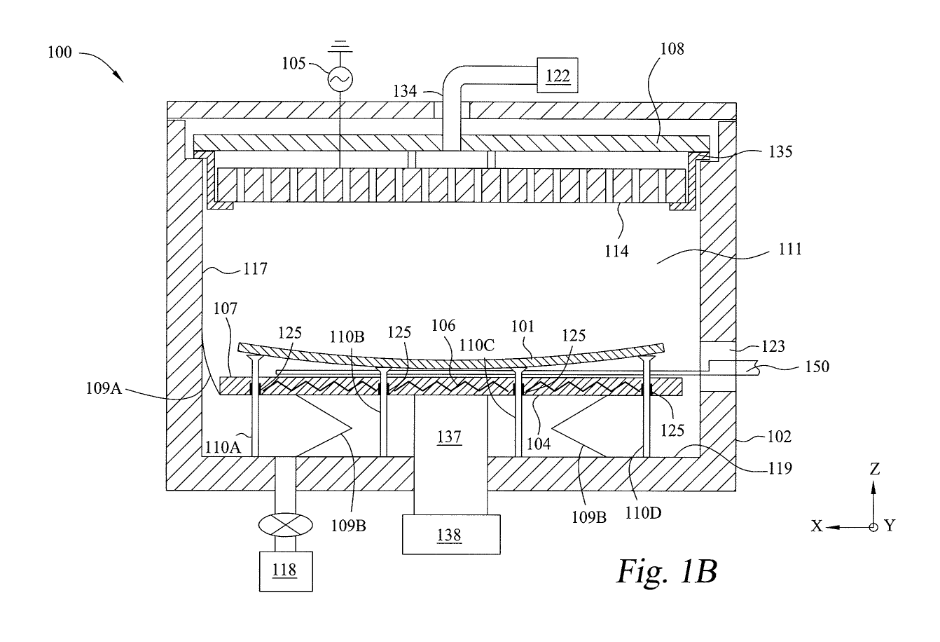

FIG. 1A is a schematic cross-sectional view of one embodiment of a processing system 100. In one embodiment, the processing system 100 is configured to process flexible media, such as a large area substrate 101, using plasma to form structures and devices on the large area substrate 101. The structures formed by the processing system 100 may be adapted for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters. The structures may include one or more junctions used to form part of a thin film photovoltaic device or solar cell. In another embodiment, the structures may be a part of a thin film transistor (TFT) used to form a LCD or TFT type device. It is also contemplated that the processing system 100 may be adapted to process substrates of other sizes and types, and may be used to fabricate other structures.

As shown in FIG. 1A, the processing system 100 generally comprises a chamber body 102 including a sidewall 117, a bottom 119 and a backing plate 108 defining a processing volume 111. A lid may be disposed over the backing plate 108. A susceptor or substrate support 104 is disposed in the processing volume 111 opposing a showerhead assembly 114. The substrate support 104 is adapted to support the substrate 101 on an upper or support surface 107 during processing. The substrate support 104 is also coupled to an actuator 138 via a hollow shaft 137. The actuator is configured to move the substrate support 104 at least vertically to facilitate transfer of the substrate 101 and/or adjust a distance between the substrate 101 and a showerhead assembly 114. One or more support pins 110A-110D extend through the substrate support 104 through respective housings 125. Each of the support pins 110A-110D are movably disposed within a dedicated support device, such as the housing 125 that is disposed within openings 128 formed in the substrate support 104. Each of the housings 125 may be a roller bushing or a simple tubular bushing adapted to movably support a support pins, such as one of the support pins 110A-110D.

In the embodiment shown in FIG. 1A, the substrate support 104 is shown in a processing position near the showerhead assembly 114. In the processing position, the support pins 110A-110D are adapted to be flush with or slightly below the support surface 107 of the substrate support 104 to allow the substrate 101 to lie flat on the substrate support 104. A processing gas source 122 is coupled by a conduit 134 to deliver process gases through the showerhead assembly 114 and into the processing volume 111. The processing system 100 also includes an exhaust system 118 configured to apply and/or maintain negative pressure to the processing volume 111. A radio frequency (RF) power source 105 is coupled to the showerhead assembly 114 to facilitate formation of a plasma in a processing region 112. The processing region 112 is generally defined between the showerhead assembly 114 and the support surface 107 of the substrate support 104.

The showerhead assembly 114, backing plate 108, and the conduit 134 are generally formed from electrically conductive materials and are in electrical communication with one another. The chamber body 102 is also formed from an electrically conductive material. The chamber body 102 is generally electrically insulated from the showerhead assembly 114. In one embodiment, the showerhead assembly 114 is mounted on the chamber body 102 by an insulator 135. In one embodiment, the substrate support 104 is also electrically conductive, and the substrate support 104 is adapted to function as a shunt electrode to facilitate a ground return path for RF energy.

A plurality of electrical return devices 109A, 109B may be coupled between the substrate support 104 and the sidewall 117 and/or the bottom 119 of the chamber body 102. Each of the return devices 109A, 109B are flexible and/or spring-like devices that bend, flex, or are otherwise selectively biased to contact the substrate support 104, the sidewall 117 and/or the bottom 119. In one embodiment, at least a portion of the plurality of return devices 109A, 109B are thin, flexible straps that are coupled between the substrate support 104, the sidewall 117 and/or the bottom 119. In one example, the substrate support 104 may be coupled to an earthen ground through at least a portion of the plurality of return devices 109A, 109B. Alternatively or additionally, the return path may be directed by at least a portion of the plurality of return devices 109A, 109B back to the RF power source 105. In this embodiment, returning RF current will pass along the interior surface of the bottom 119 and/or sidewall 117 to return to the RF power source 105.

Using a process gas from the processing gas source 122, the processing system 100 may be configured to deposit a variety of materials on the large area substrate 101, including but not limited to dielectric materials (e.g., SiO₂, SiO_{X}N_{y′} derivatives thereof or combinations thereof), semiconductive materials (e.g., Si and dopants thereof), and/or barrier materials (e.g., SiNₓ, SiOₓN_{y} or derivatives thereof). Specific examples of dielectric materials and semiconductive materials that are formed or deposited by the processing system 100 onto the large area substrate may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the system 100 may be accomplished by using silane as the precursor gas in a hydrogen carrier gas. The showerhead assembly 114 is generally disposed opposing the substrate support 104 in a substantially parallel manner to facilitate plasma generation therebetween.

A temperature control device 106 is also disposed within the substrate support 104 to control the temperature of the substrate 101 before, during, or after processing. In one aspect, the temperature control device 106 comprises a heating element to preheat the substrate 101 prior to processing. In this embodiment, the temperature control device 106 may heat the substrate support 104 to a temperature between about 200° C. and 250° C. During processing, temperatures in the processing region 112 reach or exceed 400° C. and the temperature control device 106 may comprise one or more coolant channels to cool the substrate 101. In another aspect, the temperature control device 106 may function to cool the substrate 101 after processing. Thus, the temperature control device 106 may be coolant channels, a resistive heating element, or a combination thereof. Electrical leads for the temperature control device 106 may be routed to a power source and controller (both not shown) through the hollow shaft 137.

FIG. 1B is a schematic cross-sectional view of the processing system 100 of FIG. 1A illustrating the substrate support 104 in a transfer position. The transfer position is provided by lowering the substrate support 104 in the Z direction such that the ends of the support pins 110A-11D contact the bottom 119 of the chamber body 102. In the transfer position, the substrate 101 is positioned in a spaced-apart relationship relative to the support surface 107 of the substrate support 104. In the spaced-apart position, the substrate 101 may be removed by a robotic device. In one embodiment, the substrate 101 is lifted away from the support surface 107 in an edge first/center last manner. The edge first/center last transfer method causes the substrate 101 to be lifted and supported by the support pins 110A-11D in a bowed orientation. During processing, electrostatic charges build up between the substrate 101 and the support surface 107. After processing, a portion of this electrostatic charge remains and serves to adhere the substrate 101 to the support surface 107. The edge first/center last lifting method eases lifting of the substrate 101 by minimizing the force needed to break the residual electrostatic attraction and/or redistribute residual electrostatic forces that results in less lifting force being used. Likewise, the transfer method for a to-be-processed substrate is performed in a center first/edge last manner. The center first/edge last lowering method allows better contact between the substrate 101 and the support surface 107. For example, any air that is present between the support surface 107 and the substrate 101 is allowed to escape as the substrate 101 is lowered toward the substrate support 104.

In order to promote transfer of the substrate 101 by lifting the substrate 101 in a bowed orientation, the support pins 110A-110D are divided into groups, such as outer support pins for perimeter support and inner support pins for center support. The groups of support pins are actuated at different times and/or adapted to extend different lengths (or heights) above the support surface 107 to position the substrate 101 in the bowed orientation. In one embodiment, the outer support pins 110A, 110D are longer than the inner support pins 110B, 110C. In this embodiment, the support pins 110A-110D are adapted to contact the bottom 119 of the chamber body 102 and support the substrate 101 when the substrate support 104 is lowered by the actuator 138. The different lengths of the support pins 110A, 110D and 110B, 1100 allow the substrate 101 to be raised (or lowered) in a bowed orientation. In the transfer position, the support surface 107 of the substrate support 104 is substantially aligned with a transfer port 123 formed in the sidewall 117 which allows a blade 150 of a robot to move in the X direction between or around the support pins 110A-110D, and between the substrate 101 and the support surface 107. To remove the substrate from this position, the blade 150 moves vertically upwards (Z direction) to lift the substrate 101 from the support pins 110A-110D. The blade-supported substrate may then be removed from the chamber body 102 by retracting the blade 150 in the opposite X direction. Likewise, to place a to-be-processed substrate 101 on the support pins 110A-110D, the blade 150 moves vertically downwards (Z direction) to position the substrate on the extended support pins 110A-110D.

During a transfer operation, one or more of the support pins 110A-110D may bind within the housing 125 such that the support pins does not move relative to the housing 125. This binding may cause a support pin to break the substrate 101 as the other support pins 110A-110D continue to move relative to the respective housings 125.

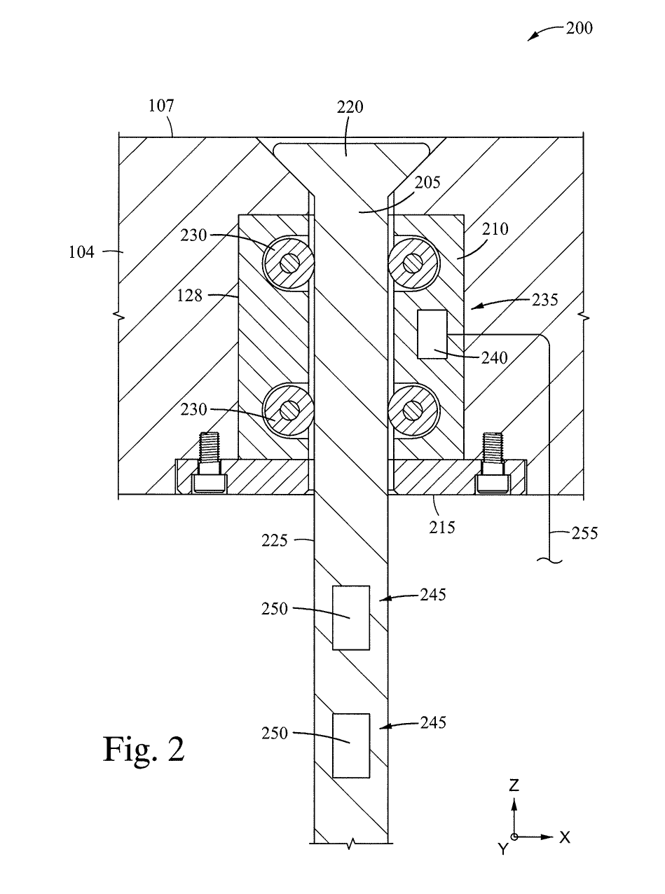

FIG. 2 is a partial cross-sectional side view of the substrate support 104 having one embodiment of a substrate support device 200 that includes a substrate support pin 205 movably disposed in a housing 210. The substrate support pin 205 may be one of the support pins 110A-110D shown in FIGS. 1A and 1B. The housing 210 may be one of the housings 125 shown in FIGS. 1A and 1B.

In one embodiment, the housing 210 is secured in the opening 128 by a base cap 215. The base cap 215 may be coupled to the substrate support 104 by threads or fasteners, such as screws, or by a press-fit. The substrate support pin 205 includes a flared head 220 and a shaft 225. The flared head 220 prevents the substrate support pin 205 from moving completely through the opening 128, thereby allowing the substrate support pin 205 to be suspended when the substrate support 104 is in a raised position as shown in FIG. 1A. In this embodiment, the substrate support device 200 includes a plurality of rollers 230 that at least partially surround the shaft 225. The rollers 230 allow movement of the substrate support pin 205 relative to the housing 210 and/or the substrate support 104 in the Z direction while preventing or minimizing lateral movement of the substrate support pin 205. The housing 210, the substrate support pin 205 as well as the rollers 230 may be made of an inert material that is not reactive with process gases or plasma, such as a ceramic or crystal material, such as sapphire, ruby, quartz and combinations thereof.

In the embodiment depicted in FIG. 2, one example of a lift pin monitoring device 235 is shown. The lift pin monitoring device 235 includes a sensor 240 disposed in a position adjacent to the substrate support pin 205. The sensor 240 is in selective communication with one or more movement indicators 245 that are adapted to move with the substrate support pin 205. In one embodiment, the lift pin monitoring device 235 is a proximity sensor or a Hall-effect sensor. In one embodiment, each of the movement indicators 245 are magnets 250. In the embodiment shown in FIG. 2, the magnets 250 are embedded within the shaft 225. It is contemplated that the magnets 250 may be disposed on the shaft 225. A signal lead 255 is coupled to the sensor 240 for communication electrical signals to a controller (not shown). The signal lead 255 may be routed through the hollow shaft 137 (shown in FIGS. 1A and 1B). Alternatively, the sensor 240 may communicate with a controller (not shown) wirelessly.

The lift pin monitoring device 235 shown in FIG. 2 detects movement of the shaft 225 relative to the housing 210 and/or the substrate support 104. The relative positions between the magnets 250 and the sensor 240 at different steps (e.g., deposition, transfer, etc.) can be predefined and/or determined empirically. If the substrate support pin 205 is jammed, or is in an abnormal position during movement of the substrate support 104, for example when the substrate support is moving in the +Z or −Z direction as shown and described in FIG. 1B, the inoperability thereof can be detected by the sensor 240. The detection of an abnormal condition may be utilized to cease movement of the substrate support 104 such that damage to the substrate can be prevented or minimized.

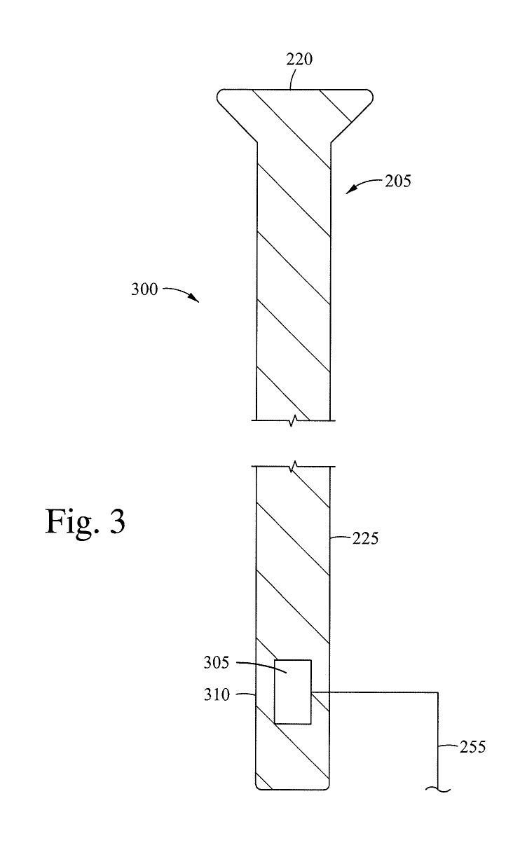

FIG. 3 is a schematic cross-sectional view of a substrate support pin 205 showing another embodiment of a lift pin monitoring device 300. The substrate support pin 205 may be one of the support pins 110A-110D located within the housings 125 shown in FIGS. 1A and 1B.

In this embodiment, the lift pin monitoring device 300 includes an acceleration sensor 305. The acceleration sensor 305 may be mounted in or on the substrate support pin 205, such as in or on the shaft 225. In one embodiment, the acceleration sensor 305 is mounted near a distal end 310 of the shaft 225, the distal end being opposite to the flared head 220. The acceleration sensor 305 may be an accelerometer, or other device that senses one or both of static and dynamic forces of acceleration. Signals from the acceleration sensor 305 may be transmitted to a controller (not shown) via a signal lead 255. Alternatively, the acceleration sensor 305 may communicate with a controller (not shown) wirelessly.

If the substrate support pin 205 is jammed, or is in an abnormal position during movement of the substrate support 104, for example when the substrate support is moving in the +Z or −Z direction as shown and described in FIG. 1B, the inoperability thereof can be detected by the acceleration sensor 305. The detection of an abnormal condition may be utilized to cease movement of the substrate support 104 such that damage to the substrate can be prevented or minimized.

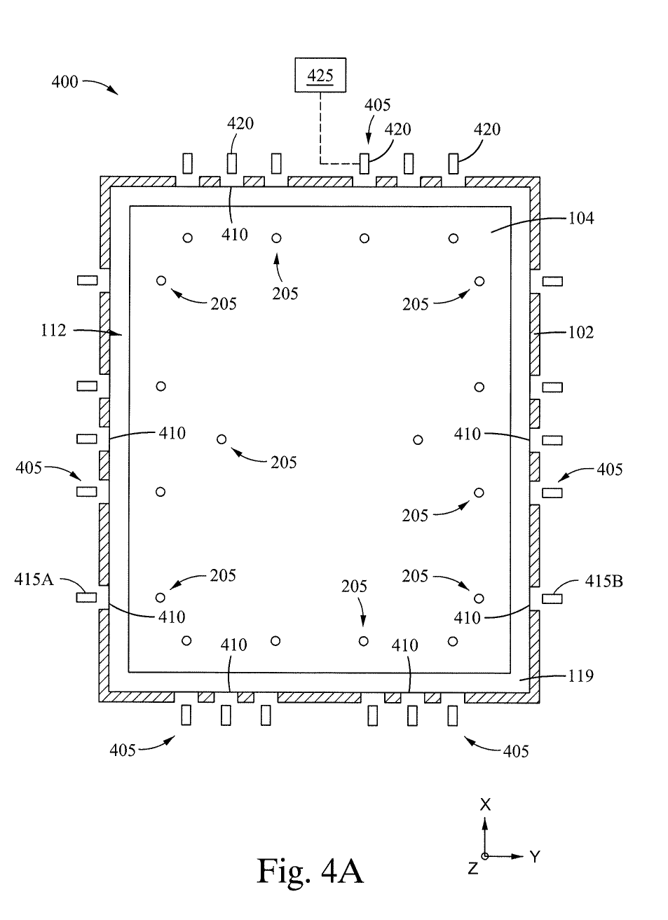

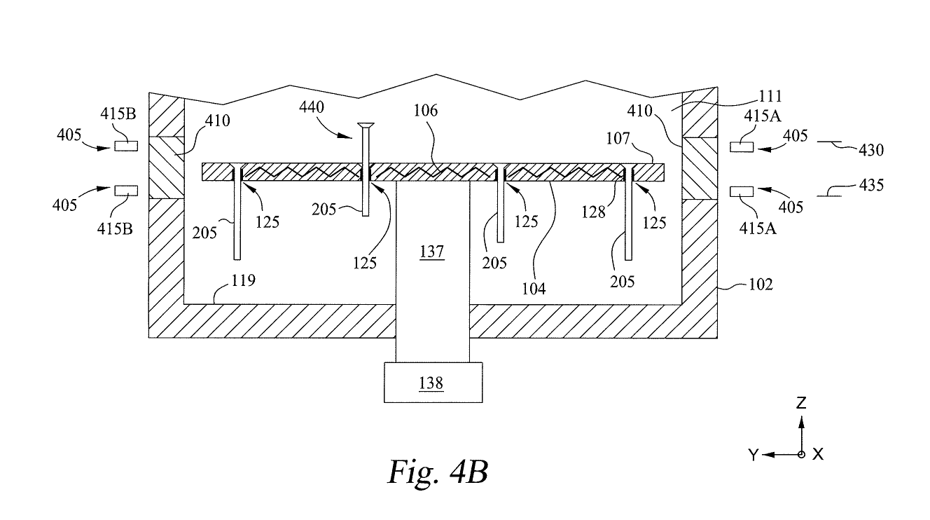

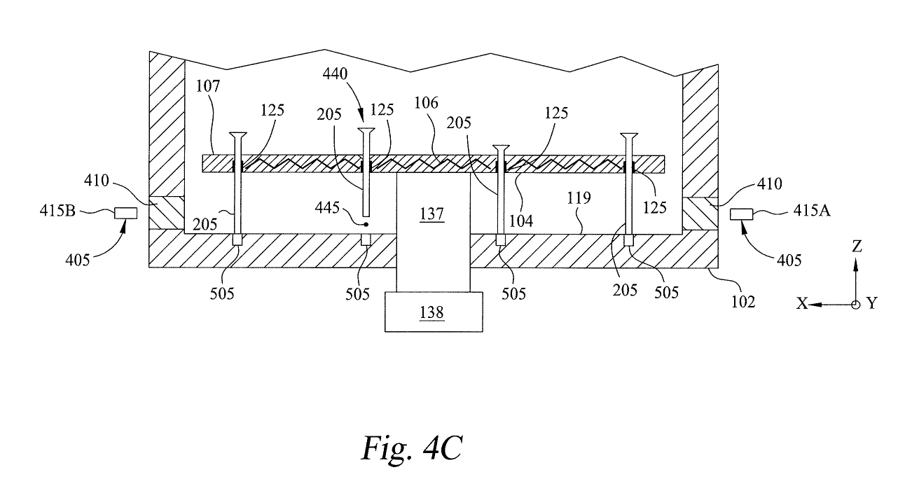

FIG. 4A is a schematic plan view of the substrate support 104 with the chamber body 102 shown in cross section. In this embodiment, a lift pin monitoring device 400 includes a plurality of optical sensors 405. Each of the optical sensors 405 are positioned adjacent to windows 410 provided in the chamber body 102. The optical sensors 405 may be optical proximity sensors, position sensors, cameras, or a combination thereof. The windows 410 may be utilized to isolate the optical sensors 405 from vacuum and/or the plasma environment inside the processing region 112. In one embodiment, each of the windows 410 may be a transparent quartz window. The position of the optical sensors 405 and the windows 410 in the Z direction may allow viewing of a portion of the processing region 112 above the support surface 107 of the substrate support 104, or a portion of the processing region 112 below the support surface 107 of the substrate support 104.

In one embodiment, pairs of the optical sensors 405 include a source emitter 415A and a receiver 415B positioned in a line-of-sight relationship. The source emitter 415A may emit light, such as laser light or a light beam in the visible spectrum or at infrared wavelengths, which is detected by the respective receiver 415B.

FIGS. 4B and 4C are schematic side cross-sectional views of the substrate support 104 and a portion of the chamber body 102 illustrating locations for the optical sensors 405. The substrate support 104 in FIGS. 4A and 4B are similar to the positions shown in FIGS. 1A and 1B, respectively.

The laser light or light beam is projected along a beam path such that one or more substrate support pins 205 are aligned therewith. In one mode of operation, an abnormal condition may occur when the substrate support moving downward in the Z direction. The source emitter 415A and the receiver 415B may be positioned at different elevations (in the Z direction), shown as levels 430 and 435, in FIG. 4B in order to monitor the one or more substrate support pins 205 during this movement. if the light or beam from the source emitter 415A is not detected by the receiver 415B, then one or more of the substrate support pins 205 are not in the desired position.

In another mode of operation, if an abnormal condition occurs when the substrate support 104 is moving up in the Z direction, the source emitter 415A and the receiver 415B are disposed at a position (level 430) higher than level 435 to detect the jammed substrate support pin(s) 205. In this mode of operation, if one or more of the substrate support pins 205 in the beam path are not in a desired position (i.e., not moving according to a desired movement), which may indicate a jammed substrate support pin 205 (shown as pin 440 in FIG. 4B), the pin 440 blocks the light or beam from reaching the receiver 415B.

In another mode of design, an abnormal condition may be determined if the light or beam from the source emitter 415A is detected by the receiver 415B. In this configuration (shown in FIG. 4C), the light or beam from the source emitter(s) 415A is emitted in the Y direction (shown by beam 445) as well as the X direction. if one of the substrate support pin(s) 205 along the beam path is not in a desired position (i.e., not moving according to a desired movement), which may indicate a jammed substrate support pin 205 (shown as pin 440 in FIG. 4B), the light or beam from the source emitter(s) 415A does not reach a respective receiver, thus detecting the abnormal condition.

In either mode of operation, the detection of an abnormal condition in the operation of one or more of the substrate support pins 205 may be utilized to cease movement of the substrate support 104 such that damage to the substrate can be prevented or minimized.

In another embodiment, one or more of the optical sensors 405 described in FIGS. 4A-4C may comprise a camera 420 (as shown and described in FIG. 4A). In this embodiment, operation of the lift pins may be monitored by personnel and/or a computer vision system 425. In one mode of operation, images and/or video captured by the camera(s) 420 may be analyzed based on stored data in the computer vision system 425. The stored data may include image data, modeling, or other data related to the operation of the substrate support 104 and/or the substrate support pins 205.

The use of camera(s) 420 as the optical sensors 405 allows personnel to observe the operation of the substrate support pins 205 and the substrate support 104, and intervene if necessary by ceasing movement of the substrate support 104 to prevent damage to the substrate. When the camera(s) 420 is coupled to the computer vision system 425, the computer vision system 425 may include an algorithm to identify jammed pins and instructions to cease movement of the substrate support 104 if an abnormal condition is detected such that damage to the substrate can be prevented or minimized.

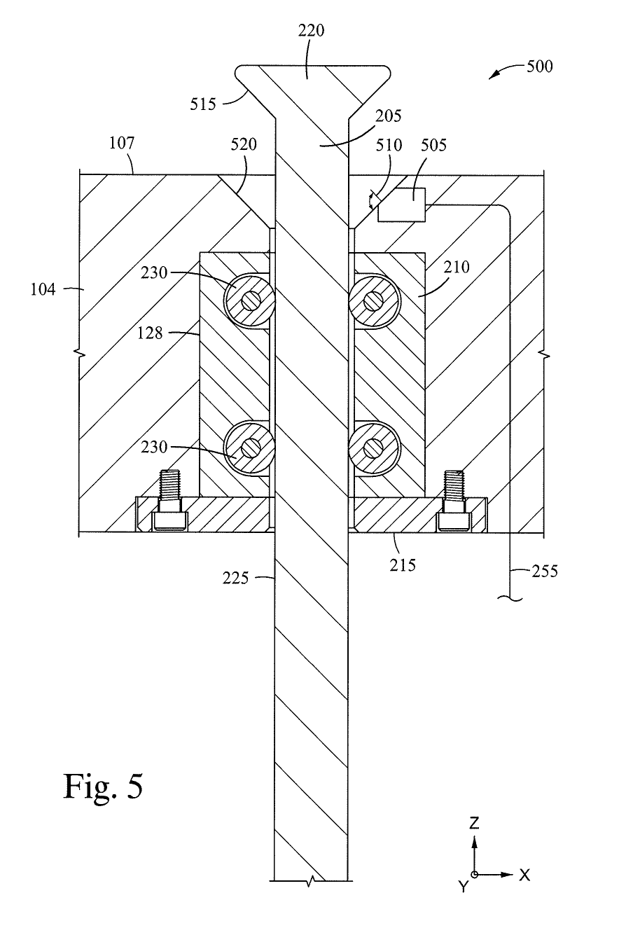

FIG. 5 is a partial cross-sectional side view of the substrate support 104 having another embodiment of a substrate support device 500 that includes a switch device 505 in proximity to the substrate support pin 205. The switch device 505 includes a toggle member 510 extending therefrom that is in a position to contact a portion of the substrate support pin 205. In one example, the toggle member 510 is adapted to contact a surface 515 of the flared head 220 of the substrate support pin 205 when the substrate support pin 205 is lowered into a recessed portion 520 of the support surface 107. Lowering of the substrate support pin 205 may be provided by moving the substrate support 104 in the Z direction (as described in more detail in FIG. 1B) to return the substrate support pin 205 to the state of the support pins 110A-11D shown in FIG. 1A. The switch device 505 may be in an open or closed state as shown in FIG. 5, but may be actuated to an opposite state when the toggle member 510 is contacted by the recessed portion 520 of the support surface 107. In one embodiment, all the support pins 110A-11D shown in FIGS. 1A and 1B include the switch device 505 as shown in FIG. 5. A signal lead 255 may be coupled between the switch device 505 and a controller (not shown) that monitors all of the switch devices 505 coupled to the support pins 110A-11D. Alternatively, the switch device 505 may communicate with a controller (not shown) wirelessly. The switch device 505 may be a micro push-down switch or toggle switch, or other suitable small switch.

For example, when the substrate support 104 is moving from the position shown in FIG. 1B to the position shown in FIG. 1A, the substrate support pin 205 should eventually reside in the recessed portion 520 of the support surface 107 if operation is normal. The normal operation is shown in FIG. 1A and, as stated above, all the support pins 110A-11D would have a respective switch device 505 in proximity thereto such that all of the support pins 110A-11D could be monitored. However, if one or more of the support pins 110A-11D of FIG. 1A (as illustrated by the substrate support pin 205 in FIG. 5) jams and does not move correctly (as compared with movement of other support pins 110A-11D), the toggle member 510 is not contacted by the surface 515 of the flared head 220 indicating an abnormal condition. The detection of an abnormal condition in the operation of one or more of the substrate support pins 205, as determined by the switch device 505, may be utilized to cease movement of the substrate support 104 such that damage to the substrate can be prevented or minimized.

Referring again to FIG. 4C, another embodiment of a lift pin monitoring device in the form of switch devices 505 disposed in or on the bottom 119 of the chamber body 102. The switch devices 505 may be the switch device 505 shown and described in FIG. 5. In this embodiment, if one or more of the substrate support pins 205 bind or jam when the substrate support 104 moves in upward in the Z direction, one or more of the switch devices 505 will sense the abnormal substrate support pin 205. Alternatively, if one or more of the substrate support pins 205 bind or jam when the substrate support 104 moves in downward in the Z direction, one or more of the switch devices 505 will sense the abnormal substrate support pin 205.

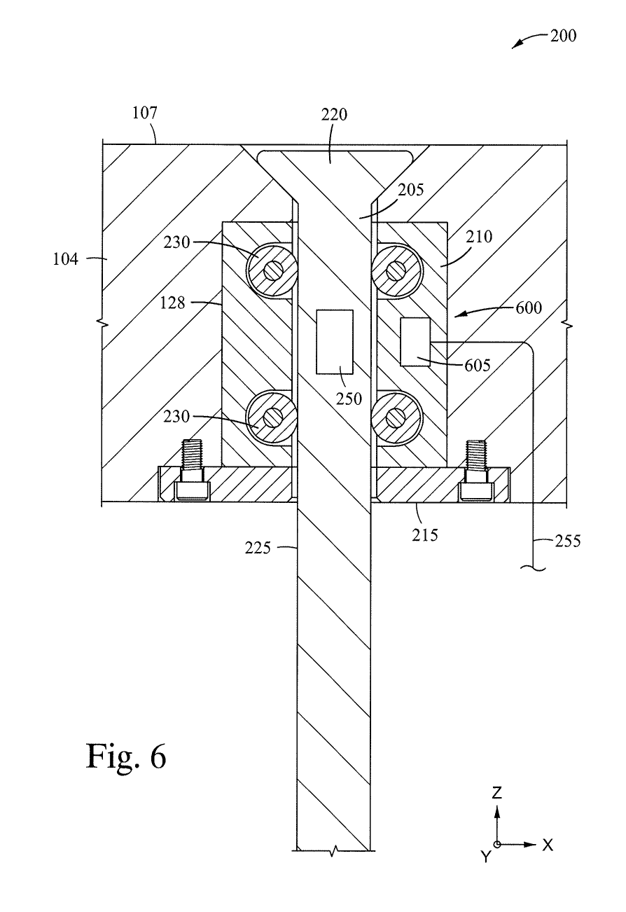

FIG. 6 is a partial cross-sectional side view of the substrate support 104 having another embodiment of a lift pin monitoring device 600. The lift pin monitoring device 600 includes a switch 605 disposed in a position adjacent to the substrate support pin 205. The switch 605 is in selective communication with a magnet 250 that is adapted to move with the substrate support pin 205. The lift pin monitoring device 600 may be a reed switch in this embodiment. A signal lead 255 may be coupled to the sensor 240 for communication electrical signals to a controller (not shown). The signal lead 255 may be routed through the hollow shaft 137 (shown in FIGS. 1A and 1B). Alternatively, the switch device 505 may communicate with a controller (not shown) wirelessly. While a single magnet 250 is shown, multiple magnets may also be provided at different locations within or on the shaft 225.

The lift pin monitoring device 600 shown in FIG. 6 detects non-movement of the shaft 225 relative to the housing 210 and/or the substrate support 104 in one mode of operation. In one example, if the substrate support pin 205 is jammed, or is in an abnormal position during movement of the substrate support 104, for example when the substrate support is moving in the +Z or −Z direction as shown and described in FIG. 1B, the inoperability thereof can be detected and movement of the substrate support 104 can be stopped by the switch 605.

While the foregoing is directed to embodiments of the disclosure, other and further embodiments of the disclosure may be devised without departing from the basic scope thereof.

What is claimed is:

1. A support pedestal for a vacuum chamber, comprising;
a body having a plurality of openings formed between two major sides of the body; and
a substrate support device disposed in each of the plurality of openings, each of the support devices comprising:
a housing disposed in the body, the housing having a bore formed therethrough; and
a support pin disposed in the bore, wherein the body includes a plurality of monitoring devices, each monitoring device positioned proximal to the support pin of each of the substrate support devices.

2. The support pedestal of claim 1, wherein the monitoring device further comprises one or more movement indicators coupled to a shaft of the support pin.

3. The support pedestal of claim 2, wherein each of the one or more movement indicators comprise a magnet.

4. The support pedestal of claim 1, wherein the monitoring device further comprises a switch.

5. The support pedestal of claim 4, wherein the switch is in selective communication with a magnet disposed in or on a shaft of the support pin.

6. A vacuum chamber, comprising:
a susceptor movably disposed in a processing volume enclosed by a bottom and a sidewall, the susceptor comprising a body having a plurality of openings formed between two major sides of the body; and
a substrate support device disposed in each of the plurality of openings, each of the support devices comprising:
a housing disposed in the body, the housing having a bore formed therethrough; and
a support pin disposed in the bore, wherein the sidewall includes a plurality of transparent windows formed therein, and an optical sensor is positioned adjacent to each of the transparent windows in a position to view each of the support devices.

7. The chamber of claim 6, wherein each of the optical sensors comprise a camera.

8. The chamber of claim 7, wherein each of the cameras are coupled to a computer vision system.

9. The chamber of claim 6, wherein a portion of the optical sensors comprise a transmitter adapted to emit a light beam.

10. The chamber of claim 9, wherein another portion of the optical sensors comprise a receiver adapted to sense the light beam.

11. A method for processing a substrate, comprising:
lowering a support pedestal disposed in a processing chamber to a position such that a plurality of support pins suspended in openings in the support pedestal contact a surface in a lower portion of the processing chamber;
further lowering the support pedestal while each of the plurality of support pins are moved relative to the support pedestal and are guided along an opening in a housing disposed in the support pedestal, and
monitoring the movement of each of the support pins during the lowering of the support pedestal.

12. The method of claim 11, wherein monitoring the operation of each of the support pins comprises monitoring acceleration of each of the support pins.

13. The method of claim 11, wherein monitoring the operation of each of the support pins comprises monitoring movement of each of the support pins.

14. The method of claim 13, wherein monitoring movement of each of the support pins comprises sending or receiving signals from a sensor disposed in a position proximate to each support pin.

15. The method of claim 14, wherein the signals are produced via interaction between a magnet and the sensor.

16. The method of claim 13, wherein monitoring movement of each of the support pins comprises sending or receiving signals from a switch disposed in a position proximate to each support pin.

17. The method of claim 16, wherein the signals are produced via interaction between a magnet and the switch.

18. The method of claim 13, wherein monitoring movement of each of the support pins comprises sending or receiving signals from a sensor disposed outside of the processing chamber.

19. The method of claim 18, wherein each of the sensors are optical sensors.

20. The method of claim 19, wherein the optical sensors are cameras.
